(19) United States
(12) Patent Application Publication
(10) Pub. No.: US 2026/0344303 A1
(43) Pub. Date: Oct. 29, 2026

(54) SEMICONDUCTOR DEVICE WITH CHANNEL LAYER INCLUDING VOID PATTERN

(71) Applicant: SK hynix Inc., Icheon-si (KR)

(72) Inventor: Won Tae KOO, Icheon-si (KR)

(21) Appl. No.: 19/366,231

(22) Filed: Oct. 22, 2025

(30) Foreign Application Priority Data
Apr. 28, 2025 (KR) 10-2025-0055679

(51) Int. Cl. H10N 70/20; H10B 63/00; H10N 70/00

(52) U.S. Cl. CPC H10N 70/253; H10B 63/00; H10N 70/245; H10N 70/823

(57) ABSTRACT

A semiconductor device according to an embodiment includes a substrate, a source electrode and a drain electrode disposed over the substrate and spaced apart from each other, a channel layer disposed between the source electrode and the drain electrode over the substrate, and including a void pattern extending in a thickness direction of the channel layer, a hydrogen conduction layer disposed on the channel layer and configured to exchange hydrogen (H) with the channel layer, and a gate electrode disposed on the hydrogen conduction layer. The channel layer includes a conductive material whose volume is expanded or contracted depending on a concentration of the hydrogen (H) accommodated by the conductive material, A size of the void pattern is controlled by volume expansion or contraction of the conductive material based upon the concentration of the hydrogen accommodated in the channel layer.

### CROSS-REFERENCE TO RELATED APPLICATION

The present application claims priority under 35 U.S.C §119(a) to Korean Application No. 10-2025-0055679, filed in the Korean Intellectual Property Office on Apr. 28, 2025, the entire contents of which are incorporated herein by reference.

### BACKGROUND

### 1. Technical Field

The present disclosure generally relates to a semiconductor device with a channel layer including a void pattern.

### 2. Related Art

Recently, resistive memory devices that store changing electrical resistances as signal information have been introduced. The resistive memory devices may be classified into a resistance change memory (resistance change RAM) device, a phase change memory (PCRAM) device, a magnetic change memory (MCRAM) device, and the like according to a resistance change occurrence factor.

Meanwhile, as an example of the resistance change memory device, a resistive memory device in the form of a field effect transistor with a channel layer formed of a resistance change material has been proposed. The resistive memory device in the form of a field effect transistor stores resistance states determined according to conductivity of the channel layer as signal information.

### SUMMARY

The present disclosure provides a semiconductor device that includes a substrate, a source electrode and a drain electrode disposed over the substrate and spaced apart from each other, a channel layer disposed between the source electrode and the drain electrode over the substrate and including a void pattern extending in a thickness direction of the channel layer, a hydrogen conduction layer disposed on the channel layer and configured to exchange hydrogen (H) with the channel layer, and a gate electrode disposed on the hydrogen conduction layer. The channel layer includes a conductive material whose volume is expanded or contracted depending on a concentration of the hydrogen (H) accommodated by the conductive material. A size of the void pattern is controlled by volume expansion or contraction of the conductive material based upon the concentration of the hydrogen accommodated in the channel layer.

The present disclosure provides a semiconductor device that includes a substrate, a source electrode and a drain electrode disposed over the substrate and spaced apart from each other, a channel layer disposed between the source electrode and the drain electrode, a hydrogen conduction layer disposed on the channel layer, and a gate electrode disposed on the hydrogen conduction layer. The channel layer may includes a void pattern penetrating the channel layer and includes a conductive material whose volume is changed depending on a concentration of hydrogen (H) accommodated in the channel layer.

The present disclosure provides a semiconductor device that includes a substrate, a source electrode and a drain electrode disposed over the substrate and spaced apart from each other, a channel layer disposed between the source electrode and the drain electrode over the substrate and including a void pattern, a hydrogen conduction layer disposed on the channel layer, and a gate electrode disposed on the hydrogen conduction layer. The channel layer includes a conductive material whose volume is expanded or contracted depending on a concentration of hydrogen (H) accommodated in the channel layer. The void pattern extends in a thickness direction of the channel layer, but the void pattern does not entirely penetrate the channel layer.

### BRIEF DESCRIPTION OF THE DRAWINGS

FIG. 1 is a schematic perspective view illustrating a semiconductor device according to an embodiment of the present disclosure.

FIG. 2 is a cross-sectional view of the semiconductor device taken along line I-I' of FIG. 1.

FIG. 3 is a plan view of a channel layer viewed from an upper portion of the semiconductor device of FIG. 1.

FIGS. 4A - FIG. 4C are cross-sectional views illustrating different resistance states of a semiconductor device according to an embodiment of the present disclosure.

FIGS. 5A - FIG. 5C are cross-sectional views illustrating different resistance states of a semiconductor device according to an embodiment of the present disclosure.

FIG. 6 is a schematic perspective view illustrating a semiconductor device according to an embodiment of the present disclosure.

FIG. 7 is a cross-sectional view of the semiconductor device taken along line II-II' of FIG. 6.

FIG. 8 is a schematic perspective view illustrating a semiconductor device according to an embodiment of the present disclosure.

FIG. 9 is a cross-sectional view of the semiconductor device taken along line III-III' of FIG. 8.

FIG. 10 is a schematic perspective view illustrating a semiconductor device according to an embodiment of the present disclosure.

FIG. 11 is a cross-sectional view of the semiconductor device taken along line IV-IV' of FIG. 10.

FIG. 12 is a plan view of a channel layer viewed from an upper surface of the semiconductor device of FIG. 10.

### DETAILED DESCRIPTION

Hereinafter, embodiments of the present disclosure will be described in detail with reference to the accompanying drawings. In the drawings, in order to clearly express the components of each device, the sizes of the components, such as width and thickness of the components, are enlarged. The cross-hatching throughout the figures illustrates corresponding or similar areas between the figures rather than indicating the materials associated with the areas.

The terms used herein may correspond to words selected in consideration of their functions in the embodiments, and the meanings of the terms may be construed to be different according to the ordinary skill in the art to which the embodiments belong. If expressly defined in detail, the terms may be construed according to the definitions. Unless otherwise defined, the terms (including technical and scientific terms) used herein have the same meaning as commonly understood by one of ordinary skill in the art to which the embodiments belong.

In addition, expression of a singular form of a word should be understood to include the plural forms of the word unless clearly used otherwise in the context. It will be understood that the terms “comprise”, “include”, or “have” are intended to specify the presence of a feature, a number, a step, an operation, a component, an element, a part, or combinations thereof, but not used to preclude the presence or possibility of addition one or more other features, numbers, steps, operations, components, elements, parts, or combinations thereof.

Terms used in the specification of the present disclosure are terms selected in consideration of functions in the presented embodiments, and the meaning of the terms may vary depending on the intention or custom of a user or operator in the technical field. The meanings of the terms used follow the definitions defined when specifically defined herein, and may be interpreted as meanings generally recognized by those skilled in the art in the absence of specific definitions.

Embodiments of the present disclosure are described in detail with reference to the accompanying drawings. Specific structural or functional descriptions of embodiments are provided as examples to describe concepts that are disclosed in the present application. Examples or embodiments in accordance with the concepts may be carried out in various forms, and the scope of the present disclosure is not limited to the examples or embodiments described in this specification.

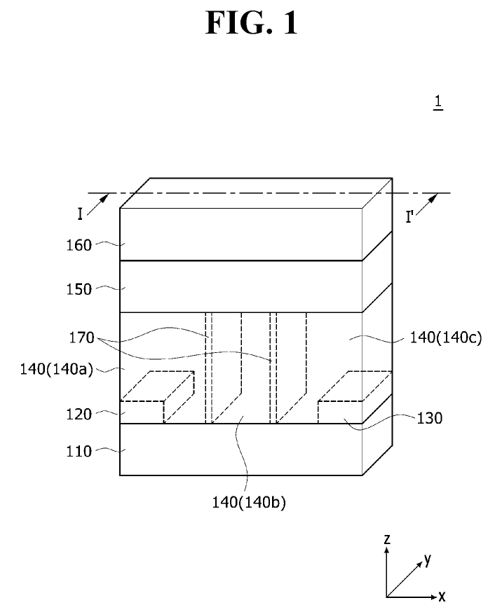

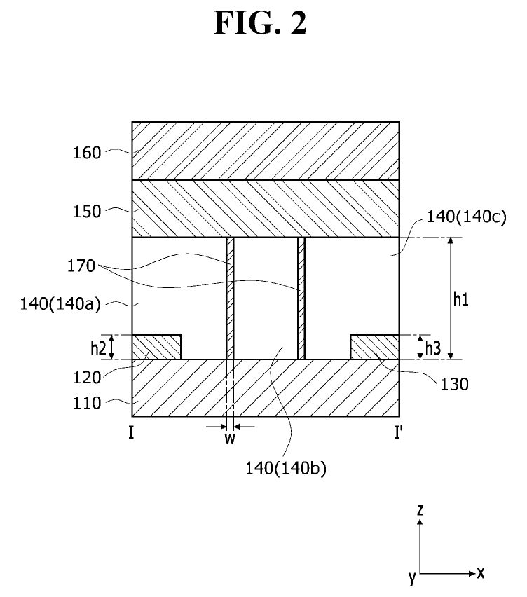

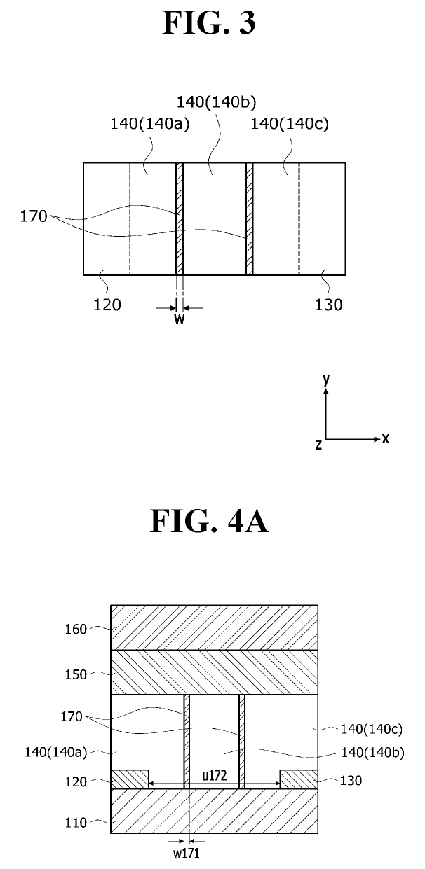

FIG. 1 is a schematic perspective view illustrating a semiconductor device 1 according to an embodiment of the present disclosure. FIG. 2 is a cross-sectional view of the semiconductor device 1 taken along line I-I' of FIG. 1. FIG. 3 is a plan view of a channel layer viewed from an upper portion of the semiconductor device 1 of FIG. 1.

Referring to FIGS. 1 - FIG. 3, the semiconductor device 1 includes a substrate 110, a source electrode 120 and a drain electrode that are disposed on the substrate 110 to be spaced apart from each other, a channel layer 140 that is disposed between the source electrode 120 and the drain electrode 130 and includes void patterns 170, a hydrogen conduction layer 150 disposed on the channel layer 140, and a gate electrode 160 disposed on the hydrogen conduction layer 150.

The substrate 110 is formed of various materials to which semiconductor integration processes are applicable. In an embodiment, the substrate 110 may include a semiconductor material. The substrate 110 is doped with an N-type or P-type dopant to have electrical conductivity.

Each of the source electrode 120 and the drain electrode 130 includes a conductive pattern. The conductive pattern may include, for example, a doped semiconductor material, metal, conductive metal nitride, conductive metal oxide, conductive metal silicide, conductive metal carbide, and a combination of two or more thereof.

The channel layer 140 includes a conductive material capable of accommodating hydrogen (H). The hydrogen (H) is dissolved in the conductive material or forms hydride through hydrogenation reaction.

In an embodiment, the hydrogen (H) may be dissolved in the conductive material in a form of neutral atoms or neutral diatomics. Alternatively, the hydrogen (H) may be dissolved in the conductive material in the form of a cation. The hydrogen (H) may be dissolved in the form of atoms, diatomics, or cations in interstitial sites of the crystal lattice of the conductive material. In another embodiment, when the conductive material is metal, the hydrogen (H) may be combined with metal to form metal hydride. In the metal hydride, the metal and the hydrogen (H) may form metallic bonding. The conductive material may include metal such as palladium (Pd), magnesium (Mg), or yttrium (Y).

When the hydrogen (H) is dissolved in the conductive material, or when the hydrogen (H) is combined with the conductive material to form the metal hydride, volume of the conductive material may be expanded. When the hydrogen (H) is out of dissolved state or the metal hydride is oxidized to the metal, the volume of the conductive material may be contracted. The degree of volume expansion of the conductive material may be proportional to, for example, concentration of the hydrogen (H) dissolved in the conductive material or the concentration of the hydrogen (H) forming the metal hydride. The degree of volume contraction of the conductive material may be proportional to, for example, the concentration of hydrogen (H) not accommodated by the conductive material in the dissolved state or the concentration of hydrogen (H) released when the metal hydride is oxidized.

The channel layer 140 includes the void patterns 170 extending in a thickness direction, that is, z-direction. The void patterns 170 penetrate the channel layer 140 in the thickness direction. Each of the void patterns 170 has a shape of a trench. The void patterns 170 extend in a width direction, that is, y-direction, perpendicular to a length direction, that is, x-direction, on an upper surface of the channel layer 140. The void patterns 170 are arranged along the x-direction.

The void patterns 170 are disposed between the source electrode 120 and the drain electrode 130. The void patterns 170 divide the channel layer 140 in the x-direction. The channel layer 140 includes first to third channel patterns 140a, 140b, and 140c that are separated from each other by the void patterns 170. In FIGS. 1 - FIG. 3, the void patterns 170 include two trench shapes extending in the y-direction, but are not necessarily limited thereto and may include one trench or three or more trenches.

The void patterns 170 are formed using a semiconductor integration process. For example, after forming the channel layer 140 over the substrate 110 in the form of a thin film, the channel layer 140 may be patterned to form the void patterns 170. Through the patterning process, the void patterns 170 having a width w along the x-direction and a length along the y-direction may be formed.

The void patterns 170 are filled with air or gas. The gas may be, for example, an inert gas such as nitrogen (N₂) or argon (Ar). When the conductive material is expanded in volume, a size of the void pattern 170 is reduced by the conductive material expanded into the void pattern 170. When the conductive material is contracted in volume, the size of the void pattern 170 is increased. As described below, the electrical conductivity of the semiconductor device 1 may be changed depending on the change in the size of the void pattern 170.

The hydrogen conduction layer 150 includes a solid electrolyte capable of conducting hydrogen (H) in the form of cations. The hydrogen conduction layer 150 may include, for example, hydrogen ion exchange polymer, metal-organic framework (MOF), covalent-organic framework (COF), sulfonated graphene, polymer-graphene composites, or a combination of two or more thereof. As an example, the hydrogen ion exchange polymer may include sulfonated tetrafluoroethylene based fluoropolymer-copolymer, polystyrene-based membranes, sulfonated polyimide (SPI)-based membranes, polyphosphazene-based membranes, polybenzimidazole (PBI)-based membranes, and the like. As another example, the MOF may be sulfonated MOF or polymer-MOF composites. Metal salts capable of forming the MOF may include salts having chemical formulas such as Zn₄O(CO₂)₆, Zn₃O(CO₂)₆, Cr₃O(CO₂)₆, In₃O(CO₂)₆, Ga₃O(CO₂)₆, Cu₂O(CO₂)₄, Zn₂O(CO₂)₄, Fe₂O(CO₂)₄, Mo₂O(CO₂)₄, Cr₂O(CO₂)₄, Co₂O(CO₂)₄, and Ru₂O(CO₂)₄. Organic ligands capable of forming the MOF may include oxalic acid, fumaric acid, H₂BDC, H₂BDC-Br, H₂BDC-OH, H₂BDC-NO₂, H₂BDC-NH₂, H₄DOT, H₂BDC-(Me)₂, H2BDC-(Cl)₂, etc. As another example, the COF may be sulfonated COF or polymer-COF composites.

The gate electrode 160 includes a conductive material. The conductive material may include, for example, a doped semiconductor material, metal, conductive metal oxide, conductive metal nitride, conductive metal silicide, conductive metal carbide, or a combination of two or more thereof.

Referring to FIG. 2, the channel layer 140, the source electrode 120, and the drain electrode 130 have height h1, height h2, and height h3, respectively. The height h1 of the channel layer 140 is greater than each of the height h2 of the source electrode 120 and the height h3 of the drain electrode 130. As shown in FIG. 2, the channel layer 140 surrounds the source electrode 120 and the drain electrode 130. Accordingly, the height of the void pattern 170 may be greater than the height h2 of the source electrode 120 and/or the height h3 of the drain electrode 130.

In some embodiments, unlike what is shown in FIGS. 1 - FIG. 3, the height h1 of the channel layer 140 may be substantially the same as the height h2 of the source electrode 120 and/or the height h3 of the drain electrode 130. Accordingly, the height of the void pattern 170 may be substantially the same as the height h2 of the source electrode 120 and/or the height h3 of the drain electrode 130.

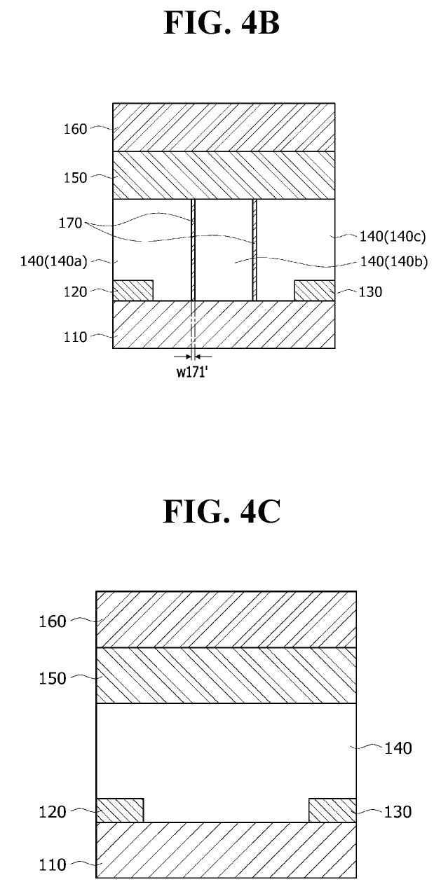

FIGS. 4A - FIG. 4C are cross-sectional views illustrating different resistance states of a semiconductor device 1 according to an embodiment of the present disclosure, for example, as shown in FIG. 1.

Referring to FIGS. 4A - FIG. 4C, the semiconductor device 1 described with reference to FIG. 1 may have a plurality of different resistance states. As an example of the resistance states that the semiconductor device 1 may have, FIG. 4A illustrates a high resistance state, FIG. 4C illustrates a low resistance state, and FIG. 4B illustrates an intermediate resistance state between the high resistance state and the low resistance state.

In an embodiment, an operation of the semiconductor device 1 may include a write operation and a read operation. The write operation of the semiconductor device 1 is performed by applying a positive bias voltage or a negative bias voltage to the gate electrode 160 while the source electrode 120, the drain electrode 130, and the substrate 110 are grounded together. The resistance state of the channel layer 140 may be changed as a size of the void pattern 170 of the channel layer 140 is changed due to the bias voltage applied to the gate electrode 160. The semiconductor device 1 may store signal information corresponding to the changed resistance state.

The read operation of the semiconductor device 1 is performed by connecting a power to the source electrode 120 and the drain electrode 130 of the semiconductor device 1 and applying a read voltage between the source electrode 120 and the drain electrode 130 to measure a current flowing through the channel layer 140. The signal information may be read by sensing the resistance state of the channel layer 140. The channel layer 140 may maintain the changed resistance state even after the positive bias voltage or negative bias voltage is removed.

Referring to FIG. 4A, the channel layer 140 includes the first channel pattern 140a, the second channel pattern 140b, and the third channel pattern 140c that are separated from each other with the void patterns 170 as boundaries. When a width w171 of the void pattern 170 has a maximum value, the semiconductor device 1 is in a high resistance state. The maximum value of the width w171 of the void pattern 170 may be about 5 % of a distance u172 between the source electrode 120 and the drain electrode 130. When the semiconductor device 1 performs a read operation in the high resistance state, electrons may conduct in the channel layer 140 in a direction parallel to a surface of the substrate 110, but may pass through the void patterns 170 by tunneling. A magnitude of the current flowing through the channel layer 140 in the high resistance state may be smaller than the magnitude of the current flowing in the low resistance state.

When a positive bias voltage is applied to the gate electrode 160 while the substrate 110 is grounded, the hydrogen (H) inside the hydrogen conduction layer 150 moves to the channel layer 140 in the form of cations. A hydrogenation reaction occurs in the conductive material inside the channel layer 140 by the injected hydrogen cations. As described above, the conductive material may include metal such as palladium (Pd), magnesium (Mg), or iridium (Y). The hydrogenation reaction may be a reaction in which the conductive material forms a solid solution or generates phase shifting. Due to the hydrogenation reaction, the lattice constant of the conductive material is increased, and thus, the volume of the conductive material is expanded. The degree of volume expansion of the conductive material may be greater when the phase shift occurs than when the conductive material forms the solid solution.

Referring to FIG. 4B, as the volume of the conductive material is expanded by the hydrogenation reaction, a widthw171′ of the void pattern 170 may be decreased to be smaller than the width w171 of the void pattern 170 in the high resistance state. As the width w171′ of the void pattern 170 is decreased, the density of the electrons tunneling and conducting the void pattern 170 is increased. Accordingly, the channel layer 140 reaches an intermediate resistance state. The current flowing through the channel layer 140 in the intermediate resistance state may be increased compared to the current flowing through the channel layer 140 in the high resistance state of FIG. 4A.

Referring to FIG. 4C, due to the volume expansion of the conductive material, the void patterns 170 disappear, and the first to third channel patterns 140a, 140b, and 140c are in contact and physically connected with each other. Accordingly, the channel layer 140 reaches the low resistance state. As the void patterns 170 disappear, the electrons move through the channel layer 140 in a direction parallel to the surface of the substrate 110 without tunneling. As the electrons move through the channel layer 140 without tunneling, the electrical conductivity of the channel layer 140 is increased. As the electrical conductivity of the channel layer 140 is increased, the resistance of the semiconductor device 1 is decreased. When the semiconductor device 1 is in the low resistance state, the magnitude of the current flowing through the channel layer 140 may be greater than the magnitude of the current flowing through the channel layer 140 in the high resistance state of FIG. 4A and the magnitude of the current flowing through the channel layer 140 in the intermediate resistance state of FIG. 4B.

An operation of converting the resistance state of the channel layer 140 into the intermediate resistance state or the low resistance state may be determined by the magnitude of the positive bias voltage applied to the gate electrode 160. The magnitude of the positive bias voltage applied when the resistance state of the channel layer 140 is converted into the low resistance state may be greater than the magnitude of the positive bias voltage applied when the resistance state of the channel layer 140 is converted into the intermediate resistance state. The magnitude of the positive bias voltage may be changed by adjusting, for example, the width of an applied pulse voltage or the number of times the pulse voltage is applied. As another example, the magnitude of the positive bias voltage may be changed by adjusting an amplitude of an applied DC voltage.

After the positive bias voltage is removed, the channel layer 140 may maintain one of the plurality of different resistance states (e.g., intermediate; low). The semiconductor device 1 may non-volatilely store a plurality of pieces of signal information corresponding to the one of the plurality of different resistance states. The operation of converting the resistance state of the semiconductor device 1 from the high resistance state to the low resistance state due to the hydrogen injection may be referred to as a first write operation of the semiconductor device 1.

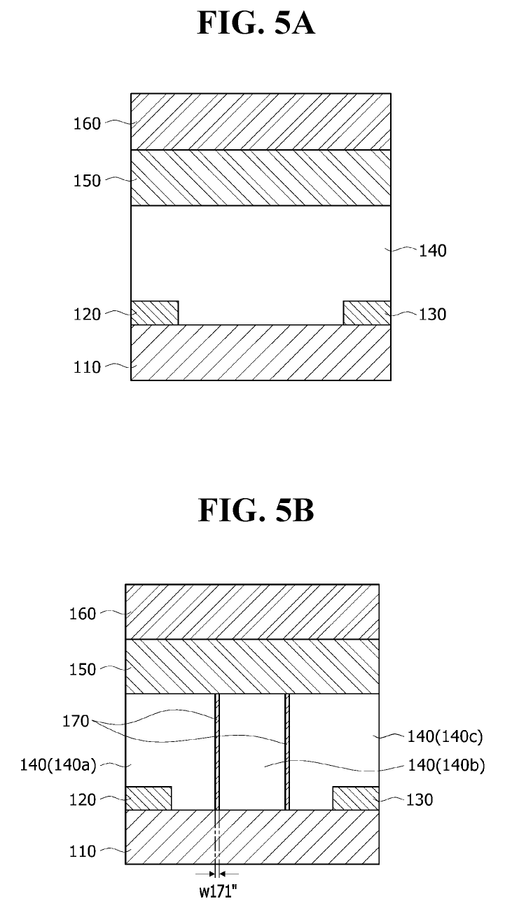

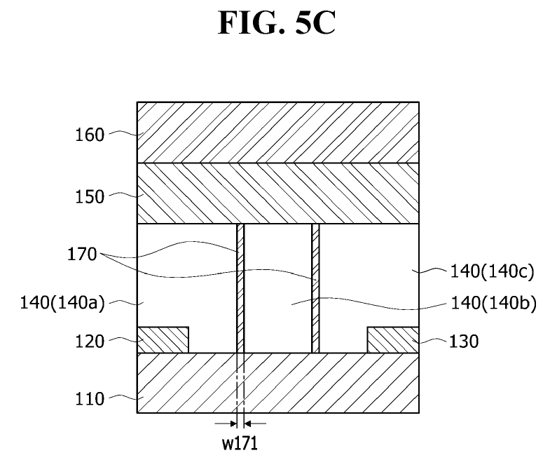

FIGS. 5A - FIG. 5C are cross-sectional views illustrating different resistance states of a semiconductor device according to an embodiment of the present disclosure, as shown in FIG. 1.

When a negative bias voltage is applied to the gate electrode 160 while the substrate 110 is grounded, hydrogen (H) ions are released from the channel layer 140 to the hydrogen conduction layer 150 and a dehydrogenation reaction occurs in the conductive material. As the lattice constant of the conductive material is changed to the lattice constant before expansion due to the dehydrogenation reaction, the void patterns 170 that have been disappeared are formed again. As the electrons inside the channel layer 140 are conducted by tunneling due to formation of the void patterns 170, the electrical conductivity of the channel layer 140 may be lowered. As the electrical conductivity of the channel layer 140 is lowered, the resistance of the semiconductor device 1 may be increased.

The resistance state of the channel layer 140 is converted from the low resistance state of FIG. 5A to the intermediate resistance state of FIG. 5B by the dehydrogenation reaction. In the intermediate resistance state, the channel layer 140 may include the first channel pattern 140a, the second channel patterns 140b, and the third channel pattern 140c that are separated from each other by the void patterns 170. The void pattern 170 has a width w171". As the dehydrogenation reaction is further performed, the resistance state of the channel layer 140 is converted into the high resistance state of FIG. 5C. In the high resistance state, the width w171 of the void pattern 170 may be greater than the width w171" of the void pattern 170 in the intermediate resistance state of FIG. 5B.

Conversion of the resistance state of the channel layer 140 into the intermediate resistance state or the high resistance state may be determined by the magnitude of the negative bias voltage applied to the gate electrode 160. The magnitude of the negative bias voltage applied when the resistance state of the channel layer 140 is converted into the high resistance state may be greater than the magnitude of the negative bias voltage applied when the resistance state of the channel layer 140 is converted into the intermediate resistance state. The magnitude of the negative bias voltage may be changed by adjusting, for example, the width of an applied pulse voltage or the number of times the pulse voltage is applied. As another example, the magnitude of the negative bias voltage may be changed by adjusting an amplitude of an applied DC voltage.

After the negative bias voltage is removed, the channel layer 140 may maintain the one of the plurality of different resistance states (e.g., intermediate; high). The semiconductor device 1 may non-volatilely store a plurality of pieces of signal information corresponding to the one of the plurality of different resistance states. Apart from the first write operation performed by applying the positive bias voltage, the operation of changing the resistance state of the semiconductor device 1 from the low resistance state to the high resistance state through the dehydrogenation reaction may be referred to as a second write operation of the semiconductor device 1. Through the above-described first and second write operations, the semiconductor device 1 according to an embodiment of the present disclosure may function as a memory device including the channel layer 140 as a memory layer.

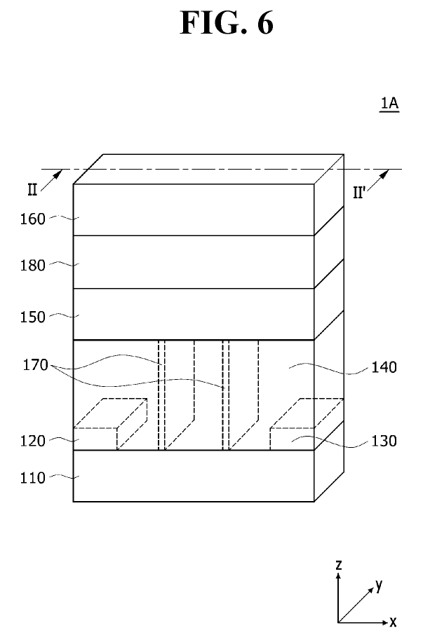

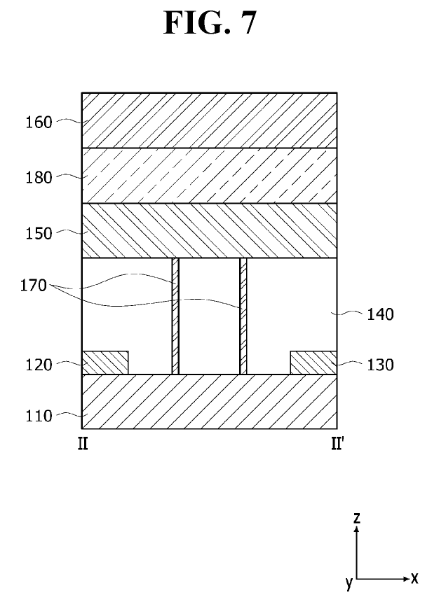

FIG. 6 is a schematic perspective view illustrating a semiconductor device 1A according to an alternative embodiment of the present disclosure. FIG. 7 is a cross-sectional view of the semiconductor device 1A taken along line II-II' of FIG. 6.

Referring to FIGS. 6 and FIG. 7, the semiconductor device 1A further includes a hydrogen source layer 180 between the hydrogen conduction layer 150 and the gate electrode 160 in the semiconductor device 1 of FIG. 1. The hydrogen source layer 180 includes hydrogen (H) therein. For example, the hydrogen (H) may have an atomic entity or diatomic entity. The hydrogen source layer 180 may include metal hydride or a hydrogen-containing semiconductor material. The metal hydride may be, for example, hydride of palladium (Pd), magnesium (Mg), or yttrium (Y). The hydrogen-containing semiconductor material may include, for example, silicon (Si) containing hydrogen or gallium arsenide (GaAs) containing hydrogen. In an embodiment, the hydrogen source layer 180 may exchange hydrogen (H) with a channel layer 140 via the hydrogen conductive layer 150.

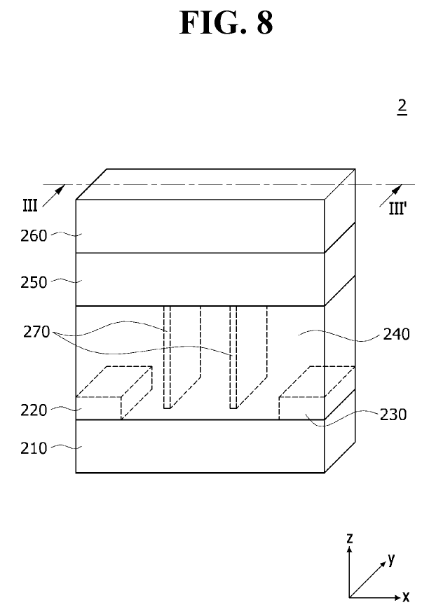

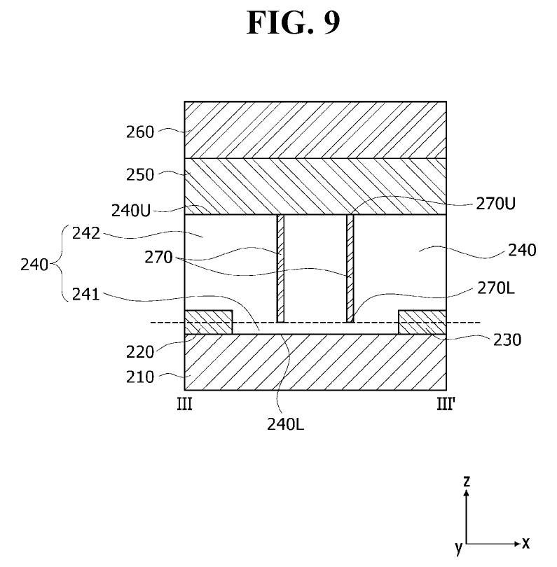

FIG. 8 is a schematic perspective view illustrating a semiconductor device 2 according to an alternative embodiment of the present disclosure. FIG. 9 is a cross-sectional view of the semiconductor device 2 taken along line III-III' of FIG. 8.

Referring to FIGS. 8 and FIG. 9, compared to the embodiment of the semiconductor device 1 described with reference to FIG. 1, the embodiment of the semiconductor device 2 has a different configuration of void patterns 270. In the semiconductor device 2, configurations of a substrate 210, a source electrode 220, a drain electrode 230, a channel layer 240, a hydrogen conduction layer 250, and a gate electrode 260 except for the void patterns 270 are substantially the same as those of the substrate 110, the source electrode 120, the drain electrode 130, the channel layer 140, the hydrogen conduction layer 150, and the gate electrode 160 of the semiconductor device 1 described with reference to FIG. 1.

Referring to FIGS. 8 and FIG. 9, the void patterns 270 are disposed not to penetrate the entirety of the channel layer 240 in an embodiment. That is the void pattern 270 partially penetrates the channel layer 240 in z-direction. In an embodiment, upper surfaces 270U of the void patterns 270 are located at the same level as an upper surface 240U of the channel layer 240, and lower surfaces 270L of the void patterns 270 are located at the same level as a lower surface 240L of the channel layer 240. In particular, the channel layer 240 includes a first channel portion 241 not including the void patterns 270 and a second channel portion 242 including the void patterns 270 along a thickness direction of the channel layer 240, that is, z-direction. The first channel portion 241 and the second channel portion 242 include substantially the same material. Because the first channel portion 241 does not include the void patterns 270, the resistance of the first channel portion 241 is lower than the resistance of the second channel portion 242. Therefore, the semiconductor device 2 can secure a relatively high channel current in a high resistance state compared to the semiconductor device 1 described in connection with FIG. 1.

In an embodiment, conversion of the resistance state of the channel layer 240 may be determined by hydrogenation reaction and dehydrogenation reaction of the second channel portion 242. A principle of having one of a plurality of different resistance states (e.g., intermediate; low) resulting from the hydrogenation reaction of the second channel portion 242 may be as illustrated in FIGS. 4A - FIG. 4C. A principle of having one of a plurality of different resistance states (e.g., intermediate; high) resulting from the dehydrogenation reaction of the second channel portion 242 may be as illustrated in FIGS. 5A - FIG. 5C.

In some embodiments, the semiconductor device 2 may further include a hydrogen source layer between the hydrogen conduction layer 250 and the gate electrode 260. A configuration of the hydrogen source layer is substantially the same as the configuration of the hydrogen source layer 180 of the semiconductor device 1A described with reference to FIGS. 6 and FIG. 7.

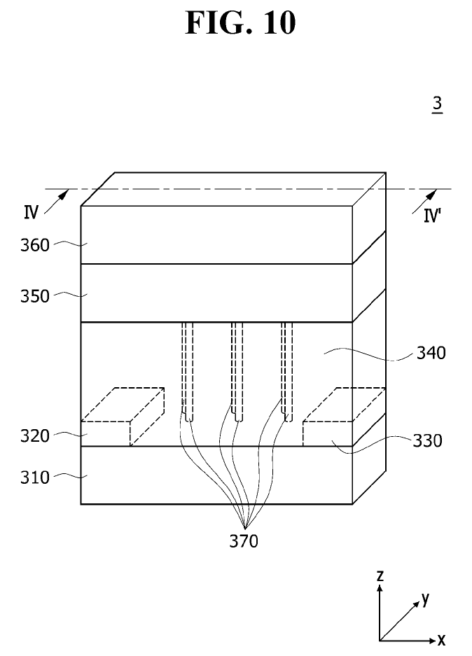

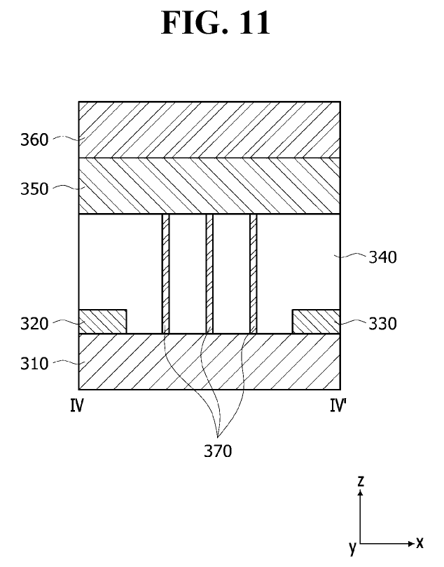

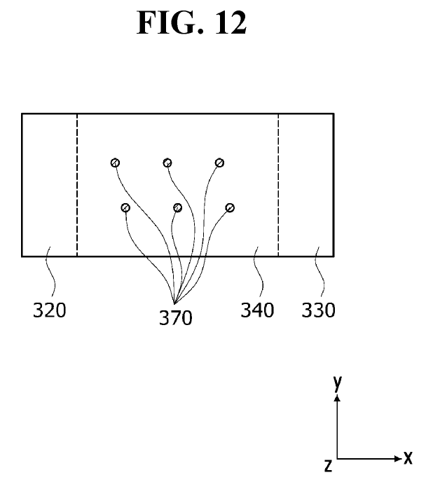

FIG. 10 is a schematic perspective view illustrating a semiconductor device 3 according to an alternative embodiment of the present disclosure. FIG. 11 is a cross-sectional view of the semiconductor device 3 taken along line IV-IV' of FIG. 10. FIG. 12 is a plan view of a channel layer viewed from an upper portion of the semiconductor device 3 of FIG. 10.

Referring to FIGS. 10 - FIG. 12, compared to the semiconductor device 1 of FIG. 1, the semiconductor device 3 has a different configuration of void patterns 370. In the semiconductor device 3, configurations of a substrate 310, a source electrode 320 and a drain electrode 330, a channel layer 340, a hydrogen conduction layer 350, and a gate electrode 360 excluding the void patterns 370 are substantially the same as those of the substrate 110, the source electrode 120 and the drain electrode 130, the channel layer 140, the hydrogen conduction layer 150, and the gate electrode 160 of the semiconductor device 1 described with reference to FIG. 1.

Referring to FIGS. 10 - FIG. 12, each of the void patterns 370 has a hole shape. The hole shape may include, for example, one of a cylinder, an elliptical column, and a polygonal column. The void patterns 370 are disposed to penetrate the channel layer 340. The void patterns 370 are uniformly distributed between the source electrode 320 and the drain electrode 330. The void patterns 370 may be filled with, for example, air or gas.

An operation principle of the semiconductor device 3 having one of a plurality of different resistance states through hydrogenation reactions (e.g., intermediate; low) and dehydrogenation reactions (e.g., intermediate; high) is substantially the same as the operation principles of the semiconductor device 1 described with reference to FIG. 1 and the semiconductor device 2 described with reference to FIG. 8.

In some embodiments, the semiconductor device 3 may further include a hydrogen source layer between the hydrogen conduction layer 350 and the gate electrode 360. The hydrogen source layer may be substantially the same as the hydrogen source layer 180 of the semiconductor device 1A described with reference to FIGS. 6 and FIG. 7.

In some embodiments, the void patterns 370 may not penetrate the entirety of the channel layer 340. The channel layer 340 may include a first channel portion not including the void patterns and a second channel portion including the void patterns along the thickness direction of the channel layer 340. The first channel portion and the second channel portion include substantially the same material. A configuration of the channel layer 340 including the first and second channel portions is self-evident from the configuration of the channel layer 240 described with reference to FIGS. 8 and FIG. 9, and therefore, a detailed description thereof is omitted.

While the above embodiments have described a semiconductor device capable of exhibiting at least three resistance states (low resistance; intermediate resistance; high resistance), this is not required. Alternative embodiments could be configured to exhibit more than three resistance states (e.g., further including intermediate low; intermediate high) by controlling one or more factors such as: the nature of the conductive material, the nature of the hydrogen conducting material, the nature of the hydrogen source material, and/or the nature of the void pattern (e.g., its shape, size, and/or extent of penetration into the channel layer).

Meanwhile, although the present specification describes various examples of structures in which the channel layer is disposed substantially parallel to the surface of the substrate, the present disclosure is not necessarily limited thereto. In some embodiments, the idea of the present disclosure may also be applied to a three-dimensional structure in which a channel layer is disposed in a direction substantially perpendicular to a surface of a substrate. In this case, a source electrode layer and a drain electrode layer may be disposed spaced apart from each other in a direction substantially perpendicular to the surface of the substrate. A hydrogen conduction layer, a hydrogen source layer, and a gate electrode layer may be disposed adjacent to the channel layer extending in the perpendicular direction.

Concepts are disclosed in conjunction with various examples and embodiments. Those skilled in the art will understand that various modifications, additions, and substitutions are possible without departing from the scope and technical concepts of the present disclosure. The embodiments disclosed in the present specification should be considered from an illustrative standpoint and not considered a restrictive standpoint. The scope of the present disclosure is not limited to the descriptions, and all distinctive features within an equivalent scope should be construed as included in the present disclosure. All changes within the meaning and range of equivalency of the claims are included within their scope.

The following embodiments are presented as additional illustrative examples of the present disclosure and are intended to support claim variations that may be pursued in this or a related application.

Embodiment 1A: A semiconductor device comprising: a substrate;
a source electrode and a drain electrode disposed over the substrate and spaced apart from each other; a channel layer disposed between the source electrode and the drain electrode over the substrate, the channel layer comprising a void pattern extending in a thickness direction of the channel layer;
a hydrogen conduction layer disposed on the channel layer and configured to exchange hydrogen (H) with the channel layer; and
a gate electrode disposed over the hydrogen conduction layer,
wherein the channel layer comprises a conductive material that accommodates hydrogen in different concentrations, and whose volume is expanded or contracted depending on a concentration of the hydrogen (H) accommodated in the channel layer, and
wherein a size of the void pattern is controlled by volume expansion or contraction of the conductive material based upon the concentration of the hydrogen accommodated in the channel layer.

Embodiment 1B: A semiconductor device as in embodiment 1A further comprising a hydrogen source layer between the hydrogen conduction layer and the gate electrode.

Embodiment 1C: A semiconductor device as in embodiments 1A or 1B wherein the void patterns penetrate the entire channel layer.

Embodiment 1D: A semiconductor device as in embodiments 1A or 1B wherein an upper surface of the void pattern is located at the same level as an upper surface of the channel layer, and wherein a lower surface of the void pattern is located at a higher level than a lower surface of the channel layer.

Embodiment 1E: A semiconductor device as in embodiments 1A, 1B, 1C, or 1D, wherein the channel layer has one of a plurality of different resistance states selected from a low resistance state, an intermediate resistance state, and a high resistance state, depending on a size of the void pattern

Embodiment 1F: A semiconductor device as in embodiments 1A, 1B, 1C, 1D, or 1E wherein the hydrogen conduction layer is configured to exchange of the hydrogen (H) between the hydrogen conduction layer and the channel layer depending on at least one of, a width of a voltage pulse, a number of voltage pulses, and a magnitude of a voltage pulse applied to the gate electrode.

Embodiment 1G. A semiconductor device as in embodiments 1A, 1B, 1C, 1D, 1E, or 1F wherein the conductive material has a lattice constant increased by hydrogenation reaction, and
wherein the channel layer has a volume expanded by a phase change due to the increased lattice constant of the conductive material.

Embodiment 1H. A semiconductor device as in embodiments 1A, 1B, 1C, 1D, 1E, 1F, or 1G wherein a size of the void pattern is decreased depending on volume expansion of the conductive material into the void pattern, and
wherein a resistance of the channel layer is decreased depending on the decrease in the size of the void pattern.

Embodiment 2A. A method comprising:
applying a voltage to a gate electrode to create an intermediate resistance state in a channel layer disposed between a source electrode and a drain electrode over a substrate, the channel layer comprising a void pattern extending in a thickness direction of the channel layer,
wherein a hydrogen conduction layer disposed on the channel layer exchanges hydrogen (H) with the channel layer,
wherein the channel layer comprises a conductive material that accommodates hydrogen in different concentrations, and whose volume is expanded or contracted depending on a concentration of the hydrogen (H) accommodated in the channel layer, and
wherein a size of the void pattern and the intermediate resistance state is controlled by volume expansion or contraction of the conductive material based upon the concentration of the hydrogen accommodated in the channel layer.

1. A semiconductor device comprising:
a substrate;
a source electrode and a drain electrode disposed over the substrate and spaced apart from each other;
a channel layer disposed between the source electrode and the drain electrode over the substrate, the channel layer comprising a void pattern extending in a thickness direction of the channel layer;
a hydrogen conduction layer disposed on the channel layer and configured to exchange hydrogen (H) with the channel layer; and
a gate electrode disposed on the hydrogen conduction layer,
wherein the channel layer comprises a conductive material whose volume is expanded or contracted depending on a concentration of the hydrogen (H) accommodated in the channel layer, and
wherein a size of the void pattern is controlled by volume expansion or contraction of the conductive material based upon the concentration of the hydrogen accommodated in the channel layer.

2. The semiconductor device of claim 1, wherein the void patterns penetrate the entire channel layer.

3. The semiconductor device of claim 1,
wherein an upper surface of the void pattern is located at the same level as an upper surface of the channel layer, and
wherein a lower surface of the void pattern is located at a higher level than a lower surface of the channel layer.

4. The semiconductor device of claim 3, wherein the channel layer comprises a first channel portion not including the void pattern and a second channel portion including the void pattern, and
wherein the void patterns partially penetrate the channel layer.

5. The semiconductor device of claim 4, wherein the first channel portion and the second channel portion comprise substantially the same material.

6. The semiconductor device of claim 1,
wherein the void pattern has a shape of a trench, and
wherein the trench extends in a width direction perpendicular to the thickness direction of the channel layer.

7. The semiconductor device of claim 1,
wherein the void pattern has a shape of a hole, and
wherein the hole comprises one of a cylinder, an elliptical column, and a polygonal column.

8. The semiconductor device of claim 1, wherein the void pattern is decreased in size as the conductive material is expanded.

9. The semiconductor device of claim 1, wherein the channel layer has one of a plurality of different resistance states depending on a size of the void pattern.

10. The semiconductor device of claim 1, wherein the conductive material comprises at least one of palladium (Pd), magnesium (Mg), and iridium (Y).

11. The semiconductor device of claim 1, wherein the hydrogen conduction layer comprises at least one selected from the group consisting of hydrogen ion exchange polymer, metal-organic framework, covalent-organic framework, sulfonated graphene, and polymer-graphene composites.

12. The semiconductor device of claim 1, further comprising a hydrogen source layer between the hydrogen conduction layer and the gate electrode.

13. The semiconductor device of claim 12, wherein the hydrogen source layer comprises metal hydride or a hydrogen-containing semiconductor material.

14. A semiconductor device comprising:
a substrate;
a source electrode and a drain electrode disposed over the substrate to be spaced apart from each other;
a channel layer disposed between the source electrode and the drain electrode;
a hydrogen conduction layer disposed on the channel layer; and
a gate electrode disposed on the hydrogen conduction layer,
wherein the channel layer comprises a void pattern penetrating the channel layer, and the channel layer comprises a conductive material whose volume is changed depending on a concentration of hydrogen (H) accommodated in the channel layer.

15. The semiconductor device of claim 14, wherein the hydrogen conduction layer is configured to exchange the hydrogen (H) between the hydrogen conduction layer and the channel layer depending on a voltage applied to the gate electrode.

16. The semiconductor device of claim 15, wherein the hydrogen conduction layer comprises at least one selected from the group consisting of hydrogen ion exchange polymer, metal-organic framework, covalent-organic framework, sulfonated graphene, and polymer-graphene composites.

17. The semiconductor device of claim 14,
wherein the conductive material has a lattice constant increased by hydrogenation reaction, and
wherein the channel layer has a volume expanded by a phase change due to the increased lattice constant of the conductive material.

18. The semiconductor device of claim 14,
wherein a size of the void pattern is decreased depending on volume expansion of the conductive material into the void pattern, and
wherein a resistance of the channel layer is decreased depending on the decrease in the size of the void pattern.

19. The semiconductor device of claim 14, wherein the channel layer has one of a plurality of different resistance states depending on a size of the void pattern.

20. A semiconductor device comprising:
a substrate;
a source electrode and a drain electrode disposed over the substrate spaced apart from each other;
a channel layer disposed between the source electrode and the drain electrode over the substrate, the channel layer comprising a void pattern;
a hydrogen conduction layer disposed on the channel layer; and
a gate electrode disposed on the hydrogen conduction layer,
wherein the channel layer comprises a conductive material whose volume is expanded or contracted depending on a concentration of hydrogen (H) accommodated in the channel layer, and
wherein the void pattern extends in a thickness direction of the channel layer, but does not entirely penetrate the channel layer.

21. The semiconductor device of claim 20,
wherein an upper surface of the void pattern is located at the same level as an upper surface of the channel layer, and
wherein a lower surface of the void pattern is located at a higher level than a lower surface of the channel layer.

22. The semiconductor device of claim 20, wherein a size of the void pattern is controlled by volume expansion or contraction of the conductive material based upon accommodation of hydrogen.
